(19) United States
(12) Patent Application Publication
(10) Pub. No.: US 2026/0129904 A1
(43) Pub. Date: May 7, 2026

(54) SEMICONDUCTOR DEVICE

(71) Applicant: FUJI ELECTRIC CO., LTD., Kawasaki-shi (JP)

(72) Inventor: Shuhei TATEMICHI, Matsumoto-city (JP)

(73) Assignee: FUJI ELECTRIC CO., LTD., Kawasaki-shi (JP)

(21) Appl. No.: 19/344,716

(22) Filed: Sep. 30, 2025

(30) Foreign Application Priority Data
Nov. 6, 2024 (JP) 2024-194643

(51) Int. Cl. H10D 30/66; H10D 62/10; H10D 62/60; H10D 62/832

(52) U.S. Cl. CPC H10D 30/668; H10D 62/102; H10D 62/126; H10D 62/60; H10D 30/665; H10D 62/8325

(57) ABSTRACT

A semiconductor device, including: a semiconductor substrate having a termination structure portion surrounding an active region in a plan view; a first semiconductor layer provided in the semiconductor substrate; a second semiconductor layer provided on the first semiconductor layer; a first parallel pn structure, in which first and second column regions are disposed repeatedly alternating with each other, provided in the second semiconductor layer and in the active region; a plurality of first semiconductor regions in the first parallel pn structure; a plurality of second semiconductor regions selectively provided in the first semiconductor regions; a plurality of gate electrodes provided respectively via gate insulating films; and a second parallel pn structure, in which third and fourth column regions are disposed repeatedly alternating with each other, provided in the second semiconductor layer and in the termination structure portion. The second parallel pn structure is longer than the first parallel pn structure.

### CROSS REFERENCE TO RELATED APPLICATIONS

This application is based upon and claims the benefit of priority of the prior Japanese Patent Application No. 2024-194643, filed on November 6, 2024, the entire contents of which are incorporated herein by reference.

### BACKGROUND OF THE INVENTION

### 1. Field of the Invention

Embodiments of the disclosure relate to a semiconductor device.

### 2. Description of the Related Art

One conventionally known superjunction semiconductor device achieves high reliability and L load avalanche breakdown (breakdown tolerance) by making the thickness of a parallel pn layer of an active area thinner than the thickness of a pn layer of a voltage withstanding area and providing an n⁺ intermediate drain layer having a higher concentration than that of an n drift region between the parallel pn layer and an n⁺ drain layer (for example, refer to Japanese Patent No. 4843843).

### SUMMARY OF THE INVENTION

According to an embodiment of the present disclosure, a semiconductor substrate of a first conductivity type, the semiconductor substrate having an active region, and a termination structure portion disposed outside the active region so as to surround a periphery of the active region in a plan view of the semiconductor device; a first semiconductor layer of the first conductivity type, provided in the semiconductor substrate at a main surface thereof, the first semiconductor layer having a dopant concentration lower than a dopant concentration of the semiconductor substrate; a second semiconductor layer of the first conductivity type, provided in the semiconductor substrate on the first semiconductor layer, the second semiconductor layer having a dopant concentration lower than the dopant concentration of the first semiconductor layer; a first parallel pn structure in which a plurality of first column regions of the first conductivity type and a plurality of second column regions of a second conductivity type are disposed repeatedly alternating with each other in a first direction parallel to the main surface, the first parallel pn structure being provided in the second semiconductor layer and in the active region; a plurality of first semiconductor regions of the second conductivity type, provided in the first parallel pn structure at a surface thereof, in the active region; a plurality of second semiconductor regions of the first conductivity type, selectively provided in the plurality of first semiconductor regions, at surfaces thereof, in the active region; a plurality of gate electrodes provided respectively via a plurality of gate insulating films, each of the plurality of gate insulating films being in contact with at least one of the plurality of first semiconductor regions and at least one of the plurality of second semiconductor regions; and a second parallel pn structure in which a plurality of third column regions of the first conductivity type and a plurality of fourth column regions of the second conductivity type are disposed repeatedly alternating with each other in the first direction, the second parallel pn structure being provided in the second semiconductor layer and in the termination structure portion. In a second direction perpendicular to the main surface, a length of the second parallel pn structure is longer than a length of the first parallel pn structure.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view depicting a structure of a silicon carbide semiconductor device according to an embodiment, along cutting line X-X’ in FIG. 3.

FIG. 2 is a cross-sectional view depicting the structure of the silicon carbide semiconductor device according to the embodiment, along cutting line Y-Y’ in FIG. 3.

FIG. 3 is a top view depicting the structure of the silicon carbide semiconductor device according to the embodiment.

FIG. 4 is a cross-sectional view depicting another structure of the silicon carbide semiconductor device according to the embodiment, along cutting line X-X’ in FIG. 3.

FIG. 5 is a cross-sectional view depicting another structure of the silicon carbide semiconductor device according to the embodiment, along cutting line X-X’ in FIG. 3.

FIG. 6 is a cross-sectional view along cutting line X-X’ in FIG. 7, depicting a structure of the conventional silicon carbide semiconductor device.

FIG. 7 is a top view of the structure of the conventional silicon carbide semiconductor device.

### DETAILED DESCRIPTION OF THE INVENTION

First, problems associated with the conventional techniques above are discussed. In a conventional semiconductor device, a problem arises in that the breakdown voltage of an edge area is difficult to increase to be higher than the breakdown voltage of the active area.

An outline of an embodiment of the present disclosure is described. A semiconductor device according to the present disclosure solving the problems above and achieving an object has the following features. The semiconductor device has an active region, and a termination structure portion provided outside the active region so as to surround a periphery of the active region. A first semiconductor layer of a first conductivity type and having a dopant concentration lower than a dopant concentration of the semiconductor substrate is provided at a main surface of a semiconductor substrate of the first conductivity type, and a second semiconductor layer of the first conductivity type and having a dopant concentration lower than the dopant concentration of the first semiconductor layer is provided on the first semiconductor layer. In the active region, a first parallel pn structure in which a plurality of first column regions of the first conductivity type and a plurality of second column regions of a second conductivity type are disposed repeatedly alternating with each other in a direction parallel to the main surface is provided in the second semiconductor layer; a plurality of first semiconductor regions of the second conductivity type is provided in a surface layer of the first parallel pn structure of the active region; a plurality of second semiconductor regions of the first conductivity type is selectively provided in a surface layer of the plurality of first semiconductor regions of the active region; and a plurality of gate electrodes is provided via a plurality of gate insulating films that are each in contact with a portion of the plurality of first semiconductor regions and a portion of the plurality of second semiconductor regions. In the termination structure portion, a second parallel pn structure in which a plurality of third column regions of the first conductivity type and a plurality of fourth column regions of the second conductivity type are disposed repeatedly alternating each other in the direction parallel to the main surface is provided in the second semiconductor layer. A column length of the second parallel pn structure is longer than a column length of the first parallel pn structure.

According to the disclosure above, the column length of the second parallel pn layer of the edge termination region is longer than the column length of the first parallel pn layer of the active region. As a result, the breakdown voltage of the edge termination region may be made higher than the breakdown voltage of the active region. Avalanche current that occurs during avalanche is distributed in the active region, which has a large surface area, and thus, destruction of the silicon carbide semiconductor device may be suppressed.

Further, in the disclosure above, in the semiconductor device according to the present disclosure, an end of the second parallel pn structure is closer to the semiconductor substrate than is an end of the first parallel pn structure.

Further, in the disclosure above, in the semiconductor device according to the present disclosure, a dopant concentration of the plurality of first column regions and the plurality of third column regions is lower than the dopant concentration of the first semiconductor layer.

Further, in the disclosure above, in the semiconductor device according to the present disclosure, a dopant concentration of the plurality of first column regions and the plurality of third column regions is higher than the dopant concentration of the first semiconductor layer.

Further, in the disclosure above, in the semiconductor device according to the present disclosure, the first semiconductor layer is configured by a first first-semiconductor-layer provided at the main surface of the semiconductor substrate and a second first-semiconductor-layer(3a) provided on the first first-semiconductor-layer, a dopant concentration of the first first-semiconductor-layer is lower than the dopant concentration of the semiconductor substrate and higher than a dopant concentration of the plurality of first column regions and the plurality of third column regions, and a dopant concentration of the second first-semiconductor-layer(3a) is lower than the dopant concentration of the semiconductor substrate and the dopant concentration of the plurality of first column regions and the plurality of third column regions.

Further, in the disclosure above, in the semiconductor device according to the present disclosure, the plurality of fourth column regions is provided at a border between the active region and the termination structure portion.

Further, in the disclosure above, in the semiconductor device according to the present disclosure, each of the plurality of third column regions and each of the plurality of fourth column regions has a first surface and a second surface opposite each, the first surfaces not being exposed and the second surfaces facing the second semiconductor layer.

Findings underlying the present disclosure are discussed. Conventionally, a semiconductor device having a superjunction (SJ) structure in which a drift layer is configured as a parallel pn layer formed by n-type regions and p-type regions disposed repeatedly alternating with each other in a direction parallel to a main surface of a substrate is known. The n-type regions and the p-type regions configuring the parallel pn layer extend linearly in a direction parallel to a main surface of the semiconductor substrate (semiconductor chip). The n-type regions and the p-type regions configuring the parallel pn layer are substantially uniform in substantially an entire area of the semiconductor substrate, from an active region of a center (chip center) of a semiconductor substrate to an end (chip end) of the semiconductor substrate.

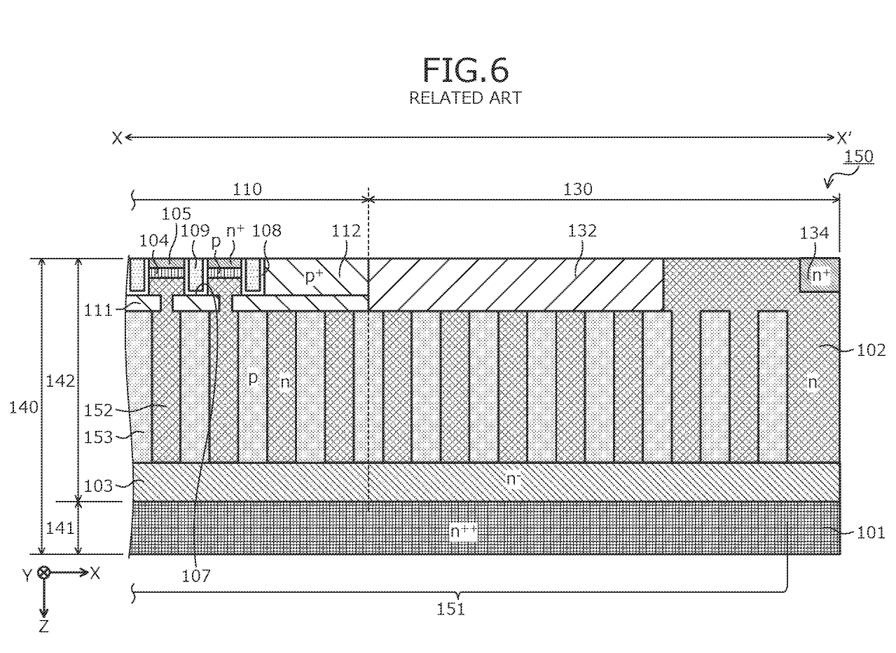

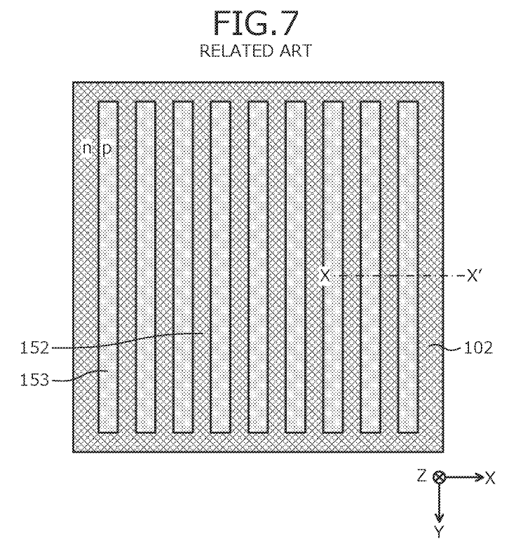

A structure of a conventional silicon carbide semiconductor device with a SJ structure is described taking metal oxide semiconductor field effect transistor (MOSFET) having insulated gates with a metal-oxide-semiconductor three-layer structure as an example. FIG. 6 is a cross-sectional view along cutting line X-X’ in FIG. 7, depicting the structure of the conventional silicon carbide semiconductor device. FIG. 7 is a top view of the structure of the conventional silicon carbide semiconductor device.

A conventional silicon carbide semiconductor device 150 depicted in FIGS. 6 and 7 is a vertical MOSFET having a general trench gate structure in an active region 110 of a semiconductor substrate (semiconductor chip) 140 containing silicon carbide and a SJ structure in which an n-type drift layer 102 is a parallel pn layer 151. The semiconductor substrate 140 has a substantially rectangular shape in a plan view. The active region 110 has a substantially rectangular shape in a plan view and is provided in a center (chip center) of the semiconductor substrate 140. A periphery of the active region 110 is surrounded by an edge termination region 130 in a plan view.

The semiconductor substrate 140 is formed by stacking an n-type epitaxial layer 142 constituting an n⁻-type buffer layer 103 and the n-type drift layer 102, on an n⁺⁺-type starting substrate 141 containing silicon carbide. The semiconductor substrate 140 has, as a front surface, a main surface having the n-type epitaxial layer 142 and is an n⁺⁺-type drain region 101. The semiconductor substrate 140 has, as a back surface, a main surface having the n⁺⁺-type starting substrate 141. The n-type epitaxial layer 142 is a portion constituting the n-type drift layer (drift region) 102 and includes the parallel pn layer 151.

At a front surface (surface facing the n-type drift layer 102) of the n⁺⁺-type starting substrate 141, a MOS gate structure configured by p-type base regions 104, n⁺-type source regions 105, gate trenches 107, gate insulating films 108, and gate electrodes 109 is provided. In the n-type drift layer 102, p⁺-type regions 111 are selectively provided so as to entirely underlie bottoms of the gate trenches 107. Of the gate trenches 107 of the active region 110, at an outermost one closest to the edge termination region 130, a corresponding one of the p⁺-type regions 111 extends from a sidewall of the outermost one of the gate trenches 107 to a later-described JTE structure 132, the sidewall facing the edge termination region 130. A p⁺-type region 112 is provided on the p⁺-type regions 111 and is exposed at the surface of the semiconductor substrate 140.

In the edge termination region 130, as a voltage withstanding structure, a junction termination extension (JTE) 132 and an n⁺-type channel stopper 134 are disposed. The JTE structure 132 surrounds the periphery of the active region 110 in a plan view.

The n⁺-type channel stopper 134 is farther outward (closer to the chip end) than is the JTE structure 132, disposed apart from the JTE structure 132, and reaches the end of the semiconductor substrate 140. The n⁺-type channel stopper 134 extends along the end of the semiconductor substrate 140 and surrounds periphery of the JTE structure 132.

The parallel pn layer 151, from the active region 110 to the edge termination region 130, is provided uniformly in substantially an entire area of the semiconductor substrate 140. The parallel pn layer 151 is a SJ structure having n-type regions 152 and p-type regions 153 disposed repeatedly alternating with each other in a first direction X parallel to the front surface of the semiconductor substrate 140. The n-type regions 152 and the p-type regions 153 of the parallel pn layer 151 extend linearly in a second direction Y that is parallel to the front surface of the semiconductor substrate 140 and orthogonal to the first direction X.

The n-type regions 152 and the p-type regions 153 of the parallel pn layer 151 are disposed in substantially an entire area of the edge termination region 130, from below the JTE structure 132 (in a direction toward the n⁺⁺-type drain region 101). The parallel pn layer 151 is in contact with the JTE structure 132 and reaches the front surface of the semiconductor substrate 140, between the JTE structure 132 and the n⁺-type channel stopper 134.

The n-type regions 152 and the p-type regions 153 of the parallel pn layer 151 are disposed evenly spaced in substantially an entire area of the semiconductor substrate 140, from the active region 110 to the edge termination region 130. Respective carrier concentrations (dopant concentrations) and widths (widths in the first direction X) of the n-type regions 152 and the p-type regions 153 of the parallel pn layer 151 are set so that the charge of any one of the n-type regions 152 and the charge of an adjacent one of the p-type regions 153 of the parallel pn layer 151 are balanced.

The respective charges being balanced means that the amount of charge expressed by a product of the carrier concentration and the width of each of the n-type regions 152 and a product of the carrier concentration and the width of each of the p-type regions 153 are substantially a same within a range that includes allowable error due to process variation.

As depicted in FIG. 6, in the conventional silicon carbide semiconductor device 150, a SJ structure is used in which the n-type regions 152 and the p-type regions 153 of the parallel pn layer 151 have a same column length in the active region 110 and the edge termination region 130. In the SJ structure, a depletion layer spreads in a lateral direction of the parallel pn layer 151 arranged orthogonal to the semiconductor substrate 140 and thus, a thickness of the depletion layer is a column length of the SJ structure.

In the conventional silicon carbide semiconductor device 150, when avalanche breakdown occurs, avalanche breakdown is caused to occur in the active region 110, which has a large area, whereby avalanche current may be shared and destruction of the silicon carbide semiconductor device 150 may be suppressed. Thus, the breakdown voltage of the edge termination region 130 is set to be higher than the breakdown voltage of the active region 110.

However, in the SJ structure, the breakdown voltage is mainly determined by the column length of the SJ structure and thus, in an instance in which the column length of the SJ structure is the same in the active region 110 and the edge termination region 130, a problem arises in that the breakdown voltage of the edge termination region 130 is difficult to make higher than the breakdown voltage of the active region 110.

Embodiments of a silicon carbide semiconductor device according to the present disclosure solving the problems of the described conventional silicon carbide semiconductor device are described in detail with reference to the accompanying drawings. In the present description and accompanying drawings, layers and regions prefixed with n or p mean that majority carriers are electrons or holes. Additionally, + or - appended to n or p means that the impurity concentration is higher or lower, respectively, than layers and regions without + or -. In the description of the embodiments below and the accompanying drawings, main portions that are identical are given the same reference numerals and are not repeatedly described. Further, with consideration of variation in manufacturing, description indicating the same or equal may be within 5%.

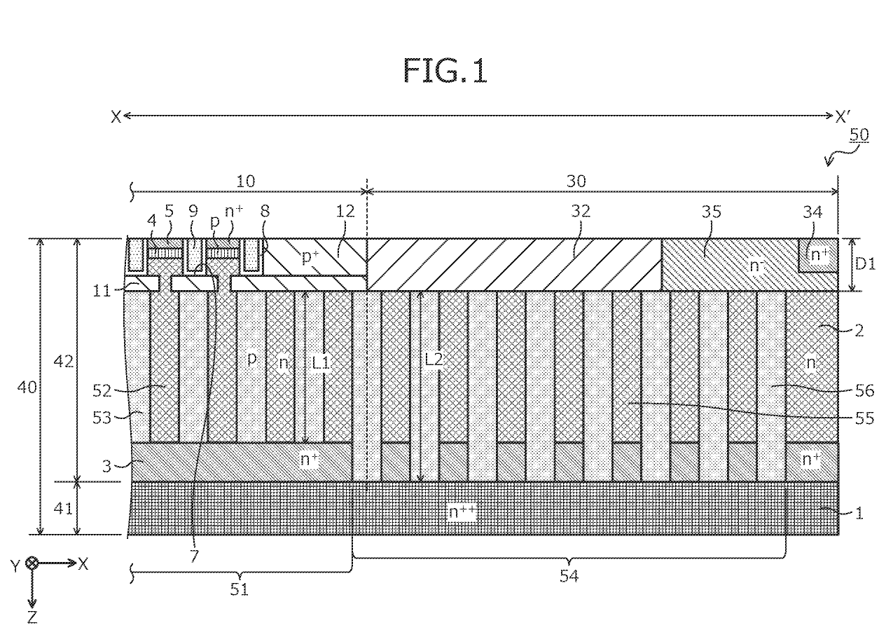

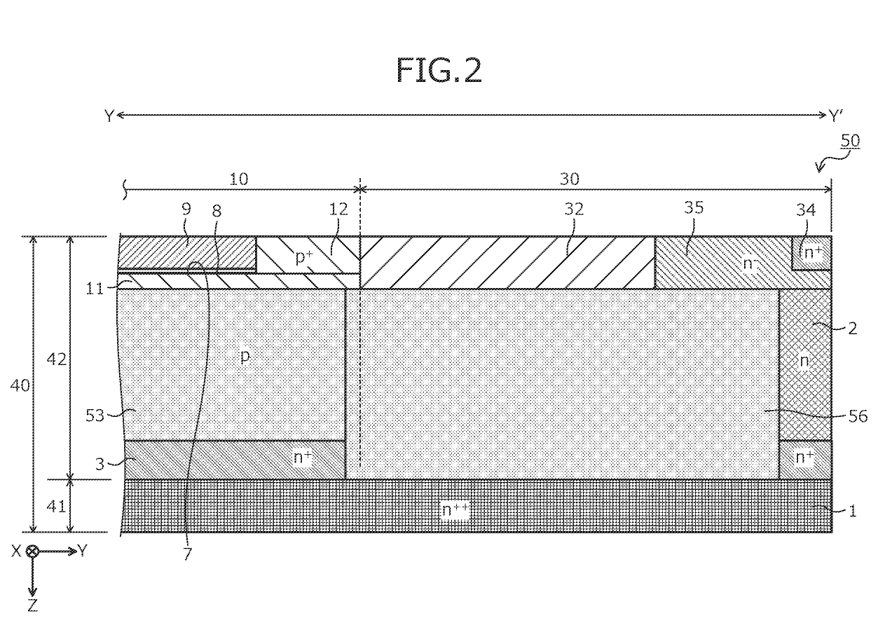

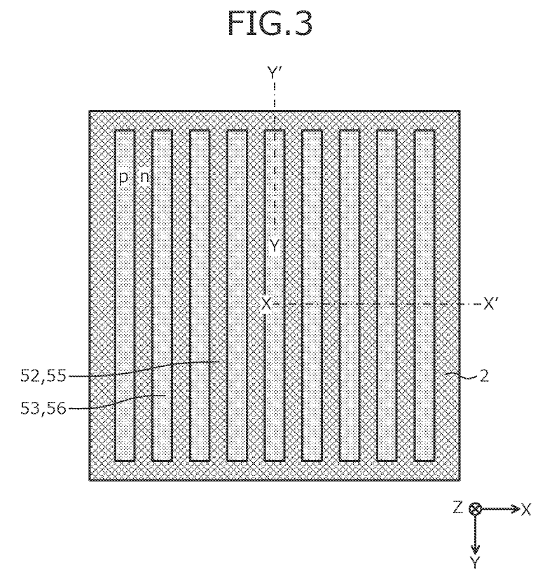

A structure of a silicon carbide semiconductor device according to an embodiment is described taking a MOSFET as an example. FIG. 1 is a cross-sectional view depicting the structure of the silicon carbide semiconductor device according to the embodiment, along cutting line X-X’ in FIG. 3. FIG. 2 is a cross-sectional view depicting the structure of the silicon carbide semiconductor device according to the embodiment, along cutting line Y-Y’ in FIG. 3. FIG. 3 is a top view depicting the structure of the silicon carbide semiconductor device according to the embodiment. In FIG. 3, the number of n-type regions (first and second first-conductivity-type regions) 52, 55 and p-type regions (first and second second-conductivity-type regions) 53, 56 of first and second parallel pn layers 51, 54 is simplified and differs in FIGS. 1 and 2.

A silicon carbide semiconductor device 50 according to the embodiment has a semiconductor substrate (semiconductor chip) 40 that contains silicon carbide (SiC) and has an active region 10 and an edge termination region (termination structure portion) 30, and is a vertical MOSFET with a trench gate structure (device structure) and a SJ structure having parallel pn layers (the first and second parallel pn layers 51, 54) as an n-type drift layer (a second semiconductor layer of a first conductivity type) 2 from the active region 10 to an edge termination region 30. The active region 10 is a region through which a main current flows when the MOSFET is in an on-state and is disposed in a center (chip center) of the semiconductor substrate 40.

The edge termination region 30 is a region between the active region 10 and an end of the semiconductor substrate 40, and surrounds a periphery of the active region 10. The active region 10 is the SJ structure having the first parallel pn layer 51 as the n-type drift layer 2. The edge termination region 30 is a SJ structure having the second parallel pn layer 54 as the n-type drift layer 2.

The edge termination region 30 has a function of relaxing electric field of the n-type drift layer 2 in the active region 10, in a front surface (first main surface) side of the semiconductor substrate 40 and sustaining the breakdown voltage. The breakdown voltage is a voltage limit at which leakage current does not increase excessively, and no malfunction or destruction of the device occurs. A border between the active region 10 and the edge termination region 30 is a border between an inner end (inner periphery) of a later-described JTE structure 32 and later-described p⁺-type regions 11, 12. In a vicinity of the border, in the active region 10, there are two layers: the p⁺-type region 11 and the p⁺-type region 12 while in the edge termination region 30, there is a single layer: the JTE structure 32.

As depicted in FIGS. 1 and 2, in the silicon carbide semiconductor device 50 according to the embodiment, in the active region 10, a general trench gate structure is provided in the front side of the semiconductor substrate 40. The trench gate structure is configured by p-type base regions (first semiconductor regions of a second conductivity type) 4, n⁺-type source regions (second semiconductor regions of the first conductivity type) 5, gate trenches 7, gate insulating films 8, and gate electrodes 9. p⁺⁺-type contact regions (not depicted) may be provided. The semiconductor substrate 40 is formed by stacking an n-type epitaxial layer 42 constituting the n-type drift layer 2, on a front surface of an n⁺⁺-type starting substrate (semiconductor substrate of the first conductivity type) 41 containing silicon carbide.

The semiconductor substrate 40 has, as a front surface, a main surface having the n-type epitaxial layer 4 and, as a back surface (second main surface), a main surface having the n⁺⁺-type starting substrate 41. The n⁺⁺-type starting substrate 41 constitutes an n⁺⁺-type drain region 1. The gate trenches 7 penetrate through the front surface of the semiconductor substrate 40 in a depth direction Z and reach an interior of the n-type epitaxial layer 42.

The gate trenches 7, for example, extend linearly (herein, the second direction Y) parallel to the front surface of the semiconductor substrate 40. In the gate trenches 7, the gate electrodes 9 are provided via the gate insulating films 8. The p-type base regions 4 extend linearly in the second direction Y, between the gate trenches 7 that are adjacent to each other. The n⁺-type source regions 5 are each selectively provided at the surface of a corresponding one of the p-type base regions 4, between the gate trenches 7 that are adjacent to each other. The p⁺⁺-type contact regions may be selectively provided at the surfaces of the p-type base regions 4, between the gate trenches 7 that are adjacent to each other.

In the active region 10, p⁺-type regions 11 are selectively provided between the first parallel pn layer 51 (the n-type drift layer 2) and the p-type base regions 4. The p⁺-type regions 11 have a function of relaxing electric field applied to the bottoms of the gate trenches 7. The p⁺-type regions 11 are disposed apart from the p-type base regions 4 and face the bottoms of the gate trenches 7 in the depth direction Z. While not depicted the p⁺-type regions 11 and the p-type base regions 4 are periodically connected to each other in the second direction Y. In the active region 10, at an outermost one of the gate trenches 7 closest to the edge termination region 30, one of the p⁺-type regions 11 extends to the JTE structure 32, from a sidewall of the outermost one of the gate trenches 7, the sidewall facing the edge termination region 30. The p⁺-type region 12 is provided on the p⁺-type regions 11 and is exposed at the surface of the semiconductor substrate 40.

In the edge termination region 30, as a voltage withstanding structure, a junction termination extension (JTE) structure 32 and an n⁺-type channel stopper region 34 are disposed. The JTE structure 32 surrounds the periphery of the active region 10 in a plan view.

The JTE structure 32 is a structure in which multiple p-type regions disposed in concentric shapes adjacent to each other surrounding the periphery of the active region 10 and arranged in descending order of dopant concentrations in a direction from the active region 10. The JTE structure 32 relaxes the concentration of electric field on the active region side and prevents destruction of the device due to an application of a voltage less than a predetermined voltage (the breakdown voltage of the edge termination region 30).

The n⁺-type channel stopper region 34 is disposed closer to the chip end than is the JTE structure 32 and is apart from the JTE structure 32, for example, the n⁺-type channel stopper region 34 reaches the end (4 linear edges) of the semiconductor substrate 40. The n⁺-type channel stopper region 34 extends along the end of the semiconductor substrate 40 and surrounds a periphery of the JTE structure 32 in a plan view.

The first parallel pn layer (first parallel pn structure) 51 is a SJ structure having the n-type regions (first column regions of the first conductivity type) 52 and the p-type regions (plurality of second column regions of a second conductivity type) 53 disposed adjacent to and repeatedly alternating with each other in the first direction X parallel to the front surface of the semiconductor substrate 40. The n-type regions 52 and the p-type regions 53 of the first parallel pn layer 51 extend linearly in the second direction Y, which is parallel to the front surface of the semiconductor substrate 40 and orthogonal to the first direction X, to a vicinity of the end of the edge termination region 30. Further, the first parallel pn layer 51 is disposed in the active region 10 in the first direction X. Thus, a border between the first parallel pn layer 51 and the second parallel pn layer 54 is positioned at the end of the active region 10.

The charge of any one of the n-type regions 52 and the charge of an adjacent one of the p-type regions 53 of the first parallel pn layer 51 are roughly balanced. The respective charges being balanced means that the amount of charge expressed by a product of the carrier concentration (dopant concentrations) and the width of each of n-type regions of the parallel pn layer and the amount of charge expressed by the carrier concentration and the width of each of the p-type regions of the parallel pn layer are substantially the same within a range that includes allowable error due to process variation. Thus, the respective carrier concentrations and the respective widths (widths in the first direction X) of the n-type regions 52 and the p-type regions 53 are set so that the respective amounts of charge of the any one of the n-type regions 52 and the adjacent one of the p-type regions 53 of the first parallel pn layer 51 are roughly balanced.

The respective amounts of charge of the any one of the n-type regions 52 and the adjacent one of the p-type regions 53 of the first parallel pn layer 51 suffice to be roughly balanced and the respective carrier concentrations and the respective widths of the n-type regions 52 and the p-type regions 53 of the first parallel pn layer 51 are suitably set. For example, the width of each of the n-type regions 52 and the width of each of the p-type regions 53 of the first parallel pn layer 51 may be substantially the same. In this instance, the carrier concentration of the n-type regions 52 and the carrier concentration of the p-type regions 53 suffice to be set to be substantially the same. The widths thereof and the carrier concentrations thereof being substantially the same means that the widths are the same and the carrier concentrations are the same within ranges that include allowable error due to process variation.

The second parallel pn layer (second parallel pn structure) 54 is a SJ structure having the n-type regions (third column regions of the first conductivity type) 55 and the p-type regions (fourth column regions of the second conductivity type) 56 disposed adjacent to and repeatedly alternating with each other in the first direction X parallel to the front surface of the semiconductor substrate 40. The n-type regions 55 and the p-type regions 56 of the second parallel pn layer 54 extend linearly in the second direction Y parallel to the n-type regions 52 and the p-type regions 53 of the first parallel pn layer 51. The second parallel pn layer 54 is disposed in the edge termination region 30 and connected to both sides of the first parallel pn layer 51 of the active region 10, in the second direction Y. The second parallel pn layer 54 is disposed in the edge termination region 30 and is adjacent to both sides of the first parallel pn layer 51, in the first direction X. The second parallel pn layer 54 is disposed so that one of the n-type regions 55 is adjacent to an outermost one of the p-type regions 53 of the first parallel pn layer 51 in the first direction X, the one of the n-type regions 55 being closer to the chip end than is the outermost one of the p-type regions 53. Further, the second parallel pn layer 54 is disposed closer to the chip end than is an outer end of the JTE structure 32 in the first direction X so that at least one of the p-type regions 56 is disposed closer to the chip end than is the outer end of (outer periphery) of the JTE structure 32 in the first direction X.

The p-type regions 56 of the second parallel pn layer 54 are disposed closer to the chip end in the first direction X than is the outer end of the JTE structure 32, whereby the concentration of electric field at the outer end of the JTE structure 32 when the MOSFET is off may be suppressed. The outer end of the JTE structure 32 is an outer end (end facing the chip end) of an outermost one of the p-type regions configuring the JTE structure 32.

The number of floating p-type regions 56 disposed in the edge termination region 30 is reduced by setting the above range as the range in which the second parallel pn layer 54 is disposed from the outer end of the JTE structure 32 in the first direction X. As a result, the amount of stored charge of minority carriers (holes) that accumulate in the edge termination region 30 due to switching of the MOSFET and remain without being discharged externally may be reduced. Thus, a fewer number of the p-type regions 56 disposed closer to the chip end than is the outer end of the JTE structure 32 in the first direction X is preferable.

When the second parallel pn layer 54 is within the above range from the outer end of the JTE structure 32 in the first direction X, arrangement may be to directly below (toward the n⁺⁺-type drain region 1) the n⁺-type channel stopper region 34 in the first direction X. Between the second parallel pn layer 54 and the end of the semiconductor substrate 40 in the first direction X, a standard n-type drift region 2 may be disposed. By omitting the standard n-type drift region 2 or reducing the width of the standard n-type drift region 2, the size of the semiconductor substrate 40 may be reduced correspondingly.

The n-type regions 55 and the p-type regions 56 of the second parallel pn layer 54 are in contact with the JTE structure 32 in the depth direction Z. The p-type regions 56 of the second parallel pn layer 54 that are provided closer to the chip end than is the JTE structure 32 are provided at positions of a depth D1 from the surface of the semiconductor substrate 40 and are not exposed at the surface of the semiconductor substrate 40. The depth D1 is, for example, a same as the JTE structure 32. Between the second parallel pn layer 54 provided closer to the chip end than is the JTE structure 32 and the surface of the semiconductor substrate 40, an n⁻-type layer 35 having a dopant concentration lower than a dopant concentration of the standard n-type drift region 2 is provided. As a result, outward spreading of the depletion layer is facilitated.

The charge of any one of the n-type regions 55 and the charge of an adjacent one of the p-type regions 56 of the second parallel pn layer 54 are roughly balanced. The respective carrier concentrations and the respective widths (widths in the first direction X) of the n-type regions 55 and the p-type regions 56 are set so that the charge of the any one of the n-type regions 55 and the charge of the adjacent one of the p-type regions 56 of the second parallel pn layer 54 are roughly balanced. The respective amounts of charge of the any one of the n-type regions 55 and the adjacent one of the p-type regions 56 of the second parallel pn layer 54 suffices to be roughly balanced and the respective carrier concentrations and the respective widths of the n-type regions 55 and the p-type regions 56 of the second parallel pn layer 54 are suitably set. For example, the width of each of the n-type regions 55 and the width of each of the p-type regions 56 of the second parallel pn layer 54 may be substantially a same. In this instance, the carrier concentration of the n-type regions 55 and the carrier concentration of the p-type regions 56 suffice to be set to be substantially a same.

In the SJ structure of the embodiment, a column length (length of the n-type regions 55 and the p-type regions 56) of the second parallel pn layer 54 of the edge termination region 30 is longer than a column length (length of the n-type regions 52 and the p-type regions 53) of the first parallel pn layer 51 of the active region 10. The n-type regions 55 and the p-type regions 56 are provided from a front surface of the n⁺⁺-type drain region 1 to a surface of the n⁻-type layer 35 or the JTE structure 32 facing the n⁺⁺-type drain region 1 while the n-type regions 52 and the p-type regions 53 are provided from an n⁺-type buffer layer 3 to surfaces of the p⁺-type regions 11 facing the n⁺⁺-type drain region 1. As depicted in FIGS. 1 and 2, a column length L2 of the second parallel pn layer 54 is longer than a column length L1 of the first parallel pn layer 51 (L2>L1). Further, a difference (L2-L1) of these lengths, preferably, may be 10% or more but not more than 25% of the column length L1 and more preferably, may be 15% or more but not more than 20%. A reason for this is that at more than 10% shorter, an effect of the embodiment decreases while at more than 25% longer, the on-resistance and fabrication costs increase.

The breakdown voltage of the SJ structure is determined by the column length of the SJ structure and thus, the column length of the edge termination region 30 is made longer than the column length of the active region 10, whereby the breakdown voltage of the edge termination region 30 may be made higher than the breakdown voltage of the active region 10. By the described configuration, avalanche current that occurs during avalanche is shared by the active region 10, which has a large area, whereby destruction of the silicon carbide semiconductor device may be suppressed.

Further, preferably, the second parallel pn layer 54 may be longer than the first parallel pn layer 51 in a direction to the n⁺⁺-type drain region 1. In the active region 10, the n⁺-type buffer layer (first semiconductor layer of the first conductivity type) 3 is provided between the first parallel pn layer 51 and the n⁺⁺-type drain region 1. A depletion layer that spreads below the SJ structure may be suppressed in a direction to the semiconductor substrate (the n⁺⁺-type drain region 1) by the n⁺-type buffer layer 3. Further, in the edge termination region 30 as well, the n-type regions 55 each of a same depth as the n⁺-type buffer layer 3 may have a same dopant concentration as that of the n⁺-type buffer layer 3. In this instance, to obtain balanced charge, the dopant concentration of the p-type regions 56 of the same depth as that of the n⁺-type buffer layer 3 is increased.

As depicted in FIGS. 1 and 2, in the edge termination region 30, an innermost one of the p-type regions 56 closest to the active region 10 is partially provided in the active region 10. Thus, the innermost one of the p-type regions 56 is in contact with both the p⁺-type region 12 and the JTE structure 32. For example, substantially a center of the innermost one of the p-type regions 56 may be between the active region 10 and the edge termination region 30.

Further, as depicted in FIGS. 1 and 2, while outer ends of the JTE structure 32 in the first direction X and the second direction Y are in contact with the p-type regions 56, the structure of the JTE structure 32 may be such that the outer ends are in contact with the n-type regions 55.

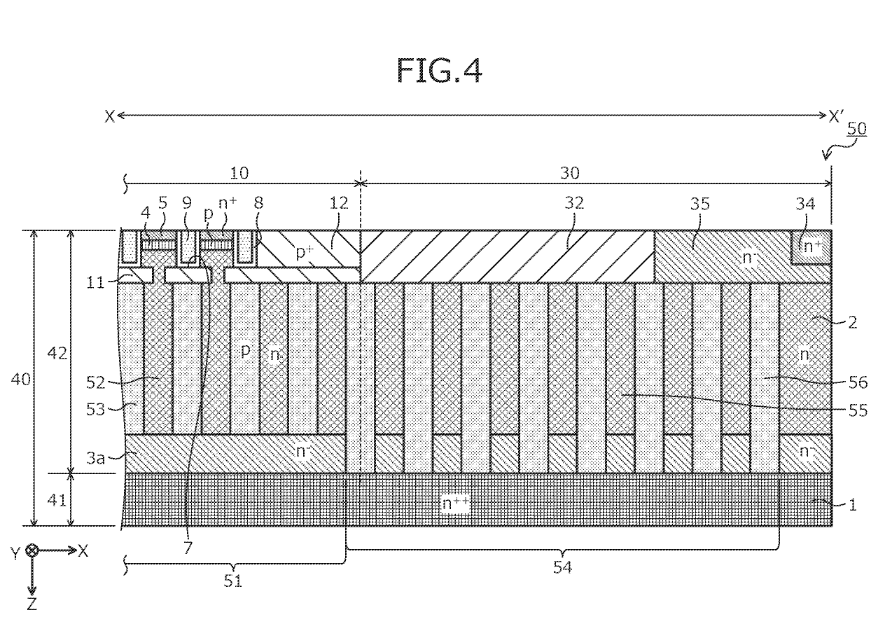

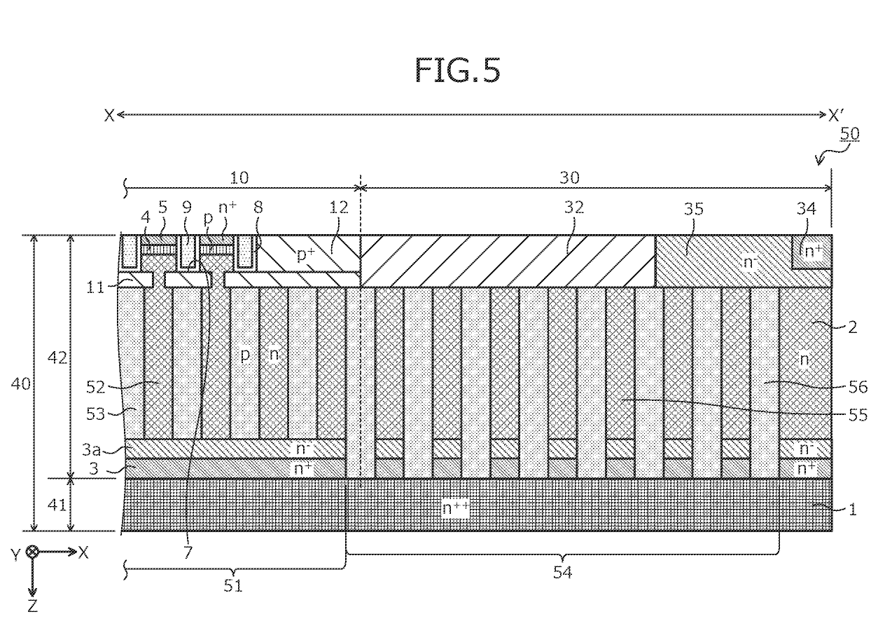

FIGS. 4 and 5 are cross-sectional views depicting another structure of the silicon carbide semiconductor device according to the embodiment, along cutting line X-X’ in FIG. 3. As depicted in FIG. 4, an n⁻-type buffer layer 3a may be provided between the first parallel pn layer 51 and the n⁺⁺-type drain region 1. Further, in the edge termination region 30 as well, the n-type regions 55, which are of a same depth as that of the n⁻-type buffer layer 3a may have a same dopant concentration as that of the n⁻-type buffer layer 3a. In this instance, to balance the charge, the dopant concentration of the p-type regions 56, which are of the same depth as that of the n⁻-type buffer layer 3a, is lowered.

As depicted in FIG. 5, the n⁺-type buffer layer (first first-semiconductor-layer) 3 is provided on the n⁺⁺-type drain region 1 and the n⁻-type buffer layer (second first-semiconductor-layer) 3a may be provided on the n⁺-type buffer layer 3. Herein, respective dopant concentrations of the n⁻-type buffer layer 3a, the n-type regions 52, the n⁺-type buffer layer 3, and the n⁺⁺-type drain region 1 increase in the order stated. Further, in the edge termination region 30 as well, the n-type regions 55 of the same depth as that of the n⁺-type buffer layer 3 may have the same dopant concentration as that of the n⁺-type buffer layer 3. In this instance, to balance the charge, the dopant concentration of the p-type regions 56, which have the same depth as that of the n⁺-type buffer layer 3, is increased. Similarly, the n-type regions 55, which have the same depth as that of the n⁻-type buffer layer 3a, may have the same dopant concentration as that of the n⁻-type buffer layer 3a. In this instance, to balance the charge, the dopant concentration of the p-type regions 56, which have the same depth as that of the n⁻-type buffer layer 3a, is reduced.

Next, a method of manufacturing the silicon carbide semiconductor device 50 according to the embodiment is described. First, on the front surface of the n⁺⁺-type starting substrate (semiconductor wafer) 41 constituting the n⁺⁺-type drain region 1, the n⁺-type buffer layer 3 and the n-type drift layer 2 having the first and second parallel pn layers 51, 54 are formed. For example, in an instance in which a multi-stage epitaxial method is used, growth of the n-type epitaxial layer 42 constituting the n⁺-type buffer layer 3 and the n-type drift layer 2 is divided into and performed in multiple stages of epitaxy (for example, 9 stages) and for each stage of epitaxial growth, in the n-type epitaxial layer 42, regions respectively constituting the n-type regions 52, 55 and the p-type regions 53, 56 are each selectively formed by ion implantation so that regions of the same conductivity type are adjacent to each other in in the depth direction Z. For example, after the first or second stage of growth of the n-type epitaxial layer 42 constituting the n⁺-type buffer layer 3, p-type ion implantation is not performed in the active region 10, whereby the length of each column of the second parallel pn layer 54 of the edge termination region 30 is made longer than the length of each column of the first parallel pn layer 51 of the active region 10 and the n⁺-type buffer layer 3 is formed between the first parallel pn layer 51 and the n⁺⁺-type drain region 1.

Further, the first and second parallel pn layers 51, 54, for example, may be formed using a trench embedding epitaxial technique after formation of the n-type epitaxial layer 42 constituting the n⁺-type buffer layer 3 and the n-type drift layer 2, in the technique trenches (hereinafter, SJ trenches) are formed in the n-type epitaxial layer 42, portions of constituting the n-type regions 52, 55 are left and the SJ trenches are embedded with a p-type epitaxial layer that constitutes the p-type regions 53, 56. For example, the length of each of the SJ trenches in the active region 10 is made shorter than the length of each of the SJ trenches in the edge termination region 30, whereby the length of each column of the second parallel pn layer 54 of the edge termination region 30 is longer than the length of each column of the first parallel pn layer 51 of the active region 10 and the n⁺-type buffer layer 3is formed between the first parallel pn layer 51 and the n⁺⁺-type drain region 1.

In another example of the structure of the silicon carbide semiconductor device according to the embodiment in FIG. 4, the n-type epitaxial layer 42 is formed as two layer including the n⁻-type buffer layer 3a and the n-type drift layer 2, whereby a structure similar to that depicted in FIGS. 1 and 2 may be formed. Further, in another example of the structure of the silicon carbide semiconductor device according to the embodiment in FIG. 5, the n-type epitaxial layer 42 may be formed as three layers including the n⁺-type buffer layer 3, the n⁻-type buffer layer 3a, and the n-type drift layer 2, whereby a structure similar to that depicted in FIGS. 1 and 2 may be formed.

Further, the p⁺-type regions 11, 12, the n⁺-type source regions 5, the p⁺⁺-type contact regions, the JTE structure 32, the n⁺-type channel stopper region 34, and the n⁻-type layer 35 may be formed by ion implantation. Thereafter, the gate trenches 7 are formed and the gate insulating films 8are formed along the front surface of the semiconductor substrate 40 and inner walls of the gate trenches 7. Next, a polysilicon layer is deposited on the front surface of the semiconductor substrate 40 so as to be embedded in the gate trenches 7 and the polysilicon layer is etched leaving portions constituting the gate electrodes 9 in the gate trenches 7. As a result, the silicon carbide semiconductor device 50 depicted in FIGS. 1 and 2 may be formed.

As described, according to the embodiment, the column length of the second parallel pn layer of the edge termination region is longer than the column length of the first parallel pn layer of the active region. As a result, the breakdown voltage of the edge termination region may be made higher than the breakdown voltage of the active region. Avalanche current that occurs during avalanche is distributed over the active region, which as a large area, and thus, destruction of the silicon carbide semiconductor device may be suppressed.

In the present disclosure above, while an instance in which a MOS gate structure is formed at the first main surface of a silicon carbide substrate is described as an example, the disclosure is not limited hereto and various modifications such as orientation of the surface of the substrate and the like are possible. Further, in the embodiments of the present disclosure, while a trench-type MOSFET is described as an example without limitation hereto, application to semiconductor devices of different configurations such as MOS-type semiconductor devices like trench-type IGBTs or the like is possible. Further, in the embodiments described above, while an instance in which silicon carbide is used as a semiconductor, a semiconductor other than silicon carbide, for example, silicon (Si), gallium nitride (GaN) or the like may be used. Further, in the present disclosure, while the first conductivity type is assumed to be an n-type and the second conductivity type is assumed to be a p-type in the embodiments, the disclosure is similarly implemented when the first conductivity type is a p-type and the second conductivity type is an n-type.

According to the disclosure above, the column length of the second parallel pn layer of the edge termination region is longer than the column length of the first parallel pn layer of the active region. As a result, the breakdown voltage of the edge termination region may be made higher than the breakdown voltage of the active region. Avalanche current that occurs during avalanche is distributed in the active region, which has a large surface area, and thus, destruction of the silicon carbide semiconductor device may be suppressed.

The semiconductor device according to the present disclosure achieves an effect in that the breakdown voltage of the edge area may be made higher than the breakdown voltage of the active area.

As described above, the silicon carbide semiconductor device according to the present disclosure is useful for high voltage semiconductor devices used in power converting equipment, power source devices of various types of industrial machines, and the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device, comprising:
a semiconductor substrate of a first conductivity type, the semiconductor substrate having
an active region, and
a termination structure portion disposed outside the active region so as to surround a periphery of the active region in a plan view of the semiconductor device;
a first semiconductor layer of the first conductivity type, provided in the semiconductor substrate at a main surface thereof, the first semiconductor layer having a dopant concentration lower than a dopant concentration of the semiconductor substrate;
a second semiconductor layer of the first conductivity type, provided in the semiconductor substrate on the first semiconductor layer, the second semiconductor layer having a dopant concentration lower than the dopant concentration of the first semiconductor layer;
a first parallel pn structure in which a plurality of first column regions of the first conductivity type and a plurality of second column regions of a second conductivity type are disposed repeatedly alternating with each other in a first direction parallel to the main surface, the first parallel pn structure being provided in the second semiconductor layer and in the active region;
a plurality of first semiconductor regions of the second conductivity type, provided in the first parallel pn structure at a surface thereof, in the active region;
a plurality of second semiconductor regions of the first conductivity type, selectively provided in the plurality of first semiconductor regions, at surfaces thereof, in the active region;
a plurality of gate electrodes provided respectively via a plurality of gate insulating films, each of the plurality of gate insulating films being in contact with at least one of the plurality of first semiconductor regions and at least one of the plurality of second semiconductor regions; and
a second parallel pn structure in which a plurality of third column regions of the first conductivity type and a plurality of fourth column regions of the second conductivity type are disposed repeatedly alternating with each other in the first direction, the second parallel pn structure being provided in the second semiconductor layer and in the termination structure portion, wherein
in a second direction perpendicular to the main surface, a length of the second parallel pn structure is longer than a length of the first parallel pn structure.

2. The semiconductor device according to claim 1, wherein
in the second direction, an end of the second parallel pn structure is closer to the semiconductor substrate than is an end of the first parallel pn structure.

3. The semiconductor device according to claim 1, wherein
each of a dopant concentration of the plurality of first column regions and a dopant concentration of the plurality of third column regions is lower than the dopant concentration of the first semiconductor layer.

4. The semiconductor device according to claim 1, wherein
each of a dopant concentration of the plurality of first column regions and a dopant concentration of the plurality of third column regions is higher than the dopant concentration of the first semiconductor layer.

5. The semiconductor device according to claim 1, wherein
the first semiconductor layer includes:
a first first-semiconductor-layer provided at the main surface of the semiconductor substrate, and
a second first-semiconductor-layer provided on the first first-semiconductor-layer,
a dopant concentration of the first first-semiconductor-layer is lower than the dopant concentration of the semiconductor substrate and higher than each of a dopant concentration of the plurality of first column regions and a dopant concentration of the plurality of third column regions, and
a dopant concentration of the second first-semiconductor-layer is lower than each of the dopant concentration of the semiconductor substrate, the dopant concentration of the plurality of first column regions, and the dopant concentration of the plurality of third column regions.

6. The semiconductor device according to claim 1, wherein
one of the plurality of fourth column regions is provided at a border between the active region and the termination structure portion.

7. The semiconductor device according to claim 1, wherein
each of the plurality of third column regions and each of the plurality of fourth column regions has a first surface and a second surface opposite each other, the first surfaces not being exposed and the second surfaces facing the second semiconductor layer.
